(19) United States
(12) Patent Application Publication
(10) Pub. No.: US 2009/0153025 A1
(43) Pub. Date: Jun. 18, 2009

(54) METHOD OF MANUFACTURING ORGANIC LIGHT EMITTING DISPLAY APPARATUS

(76) Inventors: Ja-Hyun Im, Suwon-si (KR); Kwan-Hee Lee, Suwon-si (KR); Eun-Jung Lee, Suwon-si (KR); Tae-Kwang Sung, Suwon-si (KR)

Correspondence Address: CHRISTIE, PARKER & HALE, LLP, PO BOX 7068, PASADENA, CA, 91109-7068, US

(21) Appl. No.: 12/145,690

(22) Filed: Jun. 25, 2008

(30) Foreign Application Priority Data
Dec. 13, 2007 (KR) 10-2007-0129953

(51) Int. Cl. H01J 1/62; H01J 9/00

(52) U.S. Cl. 313/503; 445/6

(57) ABSTRACT

A method of manufacturing an organic light emitting display apparatus, the method including: forming an organic light emitting device including a first electrode, a second electrode, and an intermediate layer between the first electrode and the second electrode, on a substrate, the intermediate layer including an organic light emitting layer and an electron transport layer (ETL) containing an alkali metallic compound on the organic light emitting layer; sealing the organic light emitting device; and aging the organic light emitting device, wherein the aging includes thermal treatment at a temperature from about 80 to about 150 degrees C.

### CROSS-REFERENCE TO RELATED APPLICATION

This application claims priority to and the benefit of Korean Patent Application No. 10-2007-0129953, filed on Dec. 13, 2007, in the Korean Intellectual Property Office, the entire content of which is incorporated herein by reference.

### BACKGROUND OF THE INVENTION

1. Field of the Invention

The present invention relates to a method of manufacturing an organic light emitting display apparatus, and more particularly, to a method of manufacturing an organic light emitting display apparatus to reduce or prevent a rapid reduction in brightness and to obtain stable image quality.

2. Description of the Related Art

Recently, display apparatuses have been replaced by portable and thin flat display apparatuses. Light emitting display apparatuses are flat self-luminescent display apparatuses that have a wide view angle, excellent contrast, and fast response speed. In addition, organic light emitting display apparatuses, in which an organic layer is formed of an organic material, have excellent brightness, driving voltage, and response speed compared to inorganic light emitting display apparatuses, and can provide multicolored images.

However, organic light emitting display apparatuses have drawbacks in that an organic light emitting device deteriorate over emission time, and luminous efficiency may be reduced.

In particular, when the organic light emitting display apparatuses operate at high temperatures, the organic light emitting devices are subject to deterioration. Further, even during the initial stage of utilizing the organic light emitting display apparatus, deterioration of the organic light emitting device accelerates, and it is not easy to secure long-term stable image quality.

### SUMMARY OF THE INVENTION

An aspect of an embodiment of the present invention is directed toward a method of manufacturing an organic light emitting display apparatus in which a rapid reduction in brightness is reduced or prevented when the organic light emitting display apparatus operates at high temperatures and a stable image quality can be obtained.

An embodiment of the present invention provides a method of manufacturing an organic light emitting display apparatus, the method including: forming an organic light emitting device including a first electrode, a second electrode, and an intermediate layer between the first electrode and the second electrode, on a substrate, the intermediate layer including an organic light emitting layer and an electron transport layer (ETL) containing an alkali metallic compound on the organic light emitting layer; sealing the organic light emitting device; and aging the organic light emitting device, wherein the aging includes thermal treatment at a temperature from about 80 to about 150 degrees C.

The alkali metallic compound may include one material selected from the group consisting of LiQ, NaQ, LiF, and combinations thereof.

The thermal treatment may be performed for time period from about 10 minutes to about 5 hours.

The alkali metallic compound in the ETL may include a ½ molar fraction.

From about 30 to about 70 wt % of the alkali metallic compound may be contained in the ETL.

The method may further include forming an electron injection layer (EIL) between the ETL and the second electrode.

Another embodiment of the present invention provides organic light emitting display apparatus including: a substrate; an organic light emitting device including a first electrode on the substrate, a second electrode on the first electrode, and an intermediate layer between the first electrode and the second electrode, the intermediate layer including an organic light emitting layer and an electron transport layer (ETL) containing an alkali metallic compound on the organic light emitting layer; and a sealing member sealing the organic light emitting device, wherein the organic light emitting device is aged at a temperature from about 80 to about 150 degrees C.

Another embodiment of the present invention provides a system of manufacturing an organic light emitting display apparatus, the system including: means for forming an organic light emitting device including a first electrode, a second electrode, and an intermediate layer between the first electrode and the second electrode, on a substrate, wherein the intermediate layer includes an organic light emitting layer and an electron transport layer (ETL) containing an alkali metallic compound on the organic light emitting layer; means for sealing the organic light emitting device; and means for aging the organic light emitting device with a thermal treatment at a temperature ranging from about 80 to about 150 degrees C.

### BRIEF DESCRIPTION OF THE DRAWINGS

The accompanying drawings, together with the specification, illustrate exemplary embodiments of the present invention, and, together with the description, serve to explain the principles of the present invention.

FIGS. 1, 2, 3, and 4 are schematic cross-sectional views illustrating a method of manufacturing an organic light emitting display apparatus according to an embodiment of the present invention;

FIG. 5 is a graph showing a variation in brightness when the organic light emitting display apparatus of FIG. 4 is kept at a high temperature immediately before an aging operation; and

FIG. 6 is a graph showing a variation in brightness when the organic light emitting display apparatus of FIG. 4 is kept at a high temperature immediately after an aging operation.

### DETAILED DESCRIPTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

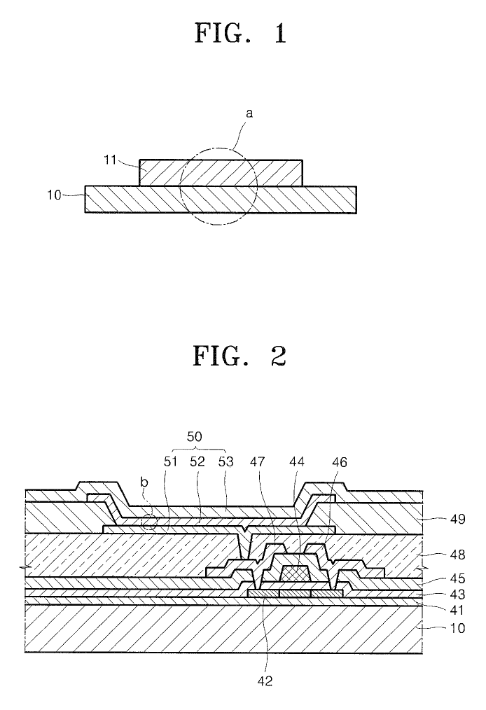

FIGS. 1 through 4 are schematic cross-sectional views illustrating a method of manufacturing an organic light emitting display apparatus according to an embodiment of the present invention. An organic light emitting display apparatus according to an embodiment of the present invention includes a substrate 10, a display portion 11, and a sealing member 20.

The display portion 11 is formed on one surface of the substrate 10, as illustrated in FIG. 1.

The substrate 10 may be formed of a transparent glass material which includes SiO₂. The substrate 10 is not limited to this and may also be formed of a transparent plastic material, a metallic foil, or the like.

The display portion 11 includes an organic light emitting device for displaying an image. The organic light emitting device may be an active element or a passive element. The organic light emitting display apparatus may be an active matrix (AM) organic light emitting display apparatus or a passive matrix (PM) organic light emitting display apparatus. Anodes and cathodes of the PM organic light emitting display apparatus are arranged in columns and rows, and scanning signals are supplied to the cathodes from a row driving circuit. As such, in the PM case, one of a plurality of rows is selected. Data signals are input to each pixel of a column driving circuit. By contrast, the AM organic light emitting display apparatus controls signals input to each pixel by using a thin film transistor (TFT) and is suitable for processing a large amount of signals and has been spotlighted as a display apparatus for moving pictures.

FIG. 2 illustrates the display portion 11 in an enlarged view of a portion (a) of FIG. 1. The display portion 11 of FIG. 2 includes an active element of an AM organic light emitting display apparatus, but is not limited to this.

Referring to FIG. 2, the display portion 11 includes an organic light emitting device 50. A buffer layer 41 may be formed on the upper surface of the substrate 10 so as to make the substrate 10 smooth and to reduce or prevent penetration of impure elements. The buffer layer 41 may be formed of SiO₂ and/or SiNₓ.

The TFT is formed on the upper surface of the substrate 10. At least one TFT is formed at each pixel and is electrically coupled to the organic light emitting device 50.

Specifically, an active layer 42 having pattern(s) (e.g., predetermined pattern(s)) is formed on the buffer layer 41. The active layer 42 may be formed of an inorganic semiconductor or organic semiconductor, such as amorphous silicon or polysilicon, and includes a source region, a drain region and a channel region.

A gate insulating layer 43 is formed of SiO₂ or SiNₓ on the active layer 42, and a gate electrode 44 is formed in a region (e.g., a predetermined region) of the gate insulating layer 43. The gate electrode 44 is formed of a material such as MoW, Al/Cu, or the like, but is not limited to this, and may be formed of various materials in consideration of their adhering property with adjacent layers, the flatness of stacked layers, electrical resistance, processibility, and/or the like.

The gate electrode 44 is connected to a gate line for applying a TFT on/off signal.

An interlayer dielectric (ILD) layer 45 is formed on the gate electrode 44, and a source electrode 46 and a drain electrode 47 are adjacent to the source and drain regions of the active layer 42 through contact holes. The TFT is covered and protected with a passivation layer 48.

The passivation layer 48 may be formed using an inorganic insulating layer and/or an organic insulating layer. The inorganic insulating layer may include SiO₂, SiNₓ, SiON, Al₂O₃, TiO₂, Ta₂O₅, HfO₂, ZrO₂, BST, and PZT, and the organic insulating layer may include a general commonly-used polymer, such as PMMA or PS, a polymer inductor having a phenol group, an acryl-based polymer, an amide-based polymer, an arylether-based polymer, an amide-based polymer, a fluid-based polymer, a p-xylene-based polymer, a vinylalcohol-based polymer, or a combination thereof. The passivation layer 48 may be formed of a composite stack body of the inorganic insulating layer and the organic insulating layer.

A first electrode 51 that is to be an anode of the organic light emitting device is formed on the passivation layer 48, and a pixel defining layer 49 is formed of an insulating material to cover the first electrode 51. After an opening (e.g., a predetermined opening) is formed in the pixel defining layer 49, an intermediate layer 52 of the organic light emitting device 50 is formed within or near a region defined by the opening. A second electrode 53 that is to be a cathode of the organic light emitting device is formed to cover all pixels. Polarities of the first and second electrodes 51 and 53 may be opposite.

The organic light emitting device 50 emits light according to the flow of current so as to display an image, and includes the first electrode 51 (which is electrically coupled to the drain electrode 47 of the TFT through a contact hole), the intermediate layer 52, and the second electrode 53.

The first electrode 51 may be patterned to correspond to each pixel by using photolithography. When the second electrode 53 is disposed on the first electrode 51, the second electrode 53 may act as a cathode by coupling the second electrode 53 to an external terminal. The second electrode 53 may be formed over an active region in which an image is displayed. When the organic light emitting display apparatus is a bottom emission type in which an image is displayed in the direction of the substrate 10, the first electrode 51 may be a transparent electrode and the second electrode 53 may be a reflective electrode. The first electrode 51 may be formed of ITO, IZO, ZnO, In₂O₃, or the like, having a large work function, and the second electrode 53 may be formed of metal having a small work function, such as Ag, Mg, Al, Pt, Pd, Au, Ni, Nd, Ir, Cr, Li, Ca, or the like.

When the organic light emitting display apparatus is a top emission type in which an image is displayed in the direction of the second electrode 53, the first electrode 51 may be a reflective electrode and the second electrode 53 may be a transparent electrode. In this case, the reflective electrode that is to be the first electrode 51 may be formed by forming a reflective layer by using metal having a small work function, such as Ag, Mg, Al, Pt, Pd, Au, Ni, Nd, Ir, Cr, Li, Ca, or a compound thereof, and then by forming ITO, IZO, ZnO, or In₂O₃, having a large work function, on the reflective layer. The transparent electrode that is to be the second electrode 53 may be formed by depositing metal having a small work function, such as Ag, Mg, Al, Pt, Pd, Au, Ni, Nd, Ir, Cr, Li, Ca, or a compound thereof, and then by forming an auxiliary electrode layer of a bus electrode line using a transparent conductive material, such as ITO, IZO, ZnO. or In₂O₃.

When the organic light emitting display apparatus is a both-side emission type, both of the first electrode 51 and the second electrode 53 may be formed as transparent electrodes.

The intermediate layer 52 is interposed between the first electrode 51 and the second electrode 53. The intermediate layer 52 includes an organic light emitting layer 523 for emitting visible rays and an electron transport layer (ETL) 524 containing an alkali metal compound. FIG. 3 illustrates the structure of the intermediate layer 52 in more detail in an enlarged view of a portion (b) of FIG. 2.

The organic light emitting layer 523 interposed between the first electrode 51 and the second electrode 53 emits light by being electrically driven by the first and second electrodes 51 and 53. The organic light emitting layer 523 may be formed of a small molecular weight organic material or polymer organic material. When the organic light emitting layer 523 is formed of a small molecular weight organic material, a hole transport layer (HTL) 522 and a hole injection layer (HIL) 521 are stacked under the organic light emitting layer 523 in the direction of the first electrode 51 as an anode, and an electron transport layer (ETL) 524 and an electron injection layer (EIL) 525 are stacked on the organic light emitting layer 523 in the direction of the second electrode 53 as a cathode. Various layers may also be stacked on the organic light emitting layer 523 if necessary. In addition, the first electrode 51 and the second electrode 53 are electrodes having opposite polarities.

As described above, the first electrode 51 serves as an anode and the second electrode 53 serves as a cathode. However, the polarities of the first and second electrodes 51 and 53 may be opposite to this. In other words, the first electrode 51 may serve as a cathode and the second electrode 53 may serve as an anode. In another embodiment of the present invention, the HTL 522 and the HIL 521 may be stacked on the organic light emitting layer 523 in the direction of the second electrode 53 as an anode, and the ETL 524 and the EIL 525 may be stacked under the organic light emitting layer 523 in the direction of the first electrode 51 as a cathode. For convenience of explanation, only the case where the first electrode 51 serves as an anode and the second electrode 53 serves as a cathode will be described.

The HIL 521 may be formed on the first electrode 51 by using vapor deposition, spin coating, or casting. The HIL 521 may also be formed using various organic materials, such as TCTA, m-MTDATA, IDE406 (made by the Idemitsu Company), Polyaniline/Dodecylbenzenesulfonic acid (Pani/DBSA) or PEDOT/PSS(Poly(3,4-ethylenedioxythiophene)/Poly(4-styrenesulfonate), which are amines having copper phthalocyanine (CuPc) or Starburst type amines, but the present invention is not limited to this.

The HTL 522 is formed on the HIL 521. The HTL 522 may also be formed using vapor deposition, spin coating or casting as in the case of the HIL 521. The HTL 522 may be formed using various organic materials such as 1,3,5-tricarbazolylbenzene, 4,4′-biscarbazolylphenyl, polyvinylcarbazol, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′diamine (TPD), N,N′-di(naphthalene-1-yl)-N,N′-diphenyl benzidine (α-NPD), N,N′-diphenyl-N,N′-bis(1-naphthyl)-(1,1′-biphenyl)-4,4′-diamine (NPB), poly(9,9-dioctylfluorene-co-N-(4-butylphenyl)diphenylamine) (TFB) or (poly(9,9-dioctylfluorene-co-bis-(4-butylphenyl-bis-N,N-phenyl-1,4-phenylenediamine) (PFB), but the present invention is not limited thereto.

The organic light emitting layer 523 is formed on the HTL 522 by using vapor deposition, spin coating, or casting. Available organic materials used in this case include copper phthalocyanie (CuPc), N,N′-Di(naphthalene-1-yl)-N,N′-diphenyl-benzidine (NPB), and tris-8-hydroxyquinoline aluminum (Alq₃).

The ETL 524 is formed on the organic light emitting layer 523 by using vapor deposition, spin coating, or casting. The ETL 524 may be formed of a material selected from the group consisting of oxadiazole, triazole, phenanthroline, benzoxazole, benzthiazole, and combinations thereof. However, the present invention is not limited to this, and Alq₃ or the like may be used in forming the ETL 524.

The ETL 524 is formed to contain an alkali metallic compound. The metallic compound contained in the ETL 524 may include a material selected from the group consisting of LiQ, NaQ, LiF, and combinations thereof. However, the present invention is not limited to this, and the ETL 524 may contain various alkali metallic compounds.

When the alkali metallic compound is used to dope the ETL 524, which is formed of an organic material, so as to improve device characteristics, the alkali metallic compound may dope at ½ molar fraction. In other words, when the molar ratio of the organic material to the alkali metallic compound included in the ETL 524 is adjusted to be about 1:1, device characteristics are optimized.

From about 30 to about 70 wt % (or from 30 to 70 wt %) of a metallic compound may be contained in the ETL 524. This can be obtained when the above-described organic materials for the ETL 524 and the alkali metallic compound are adjusted to the molar ratio of 1:1.

When the ETL 524 is formed, the alkali metallic compound is added by using co-deposition or doping. The ETL 524 includes the alkali metallic compound so that electrons can be made to more briskly flow into the organic light emitting layer 523 from a cathode. As a result, the efficiency of the organic light emitting device 50 is improved, a driving voltage is reduced, and consumed power is reduced.

The EIL 525 may be formed on the ETL 524 by using vapor deposition, spin coating, or casting. BaF₂, LiF, NaCl, CsF, Li₂O, BaO, or Liq may be used in forming the EIL 525. However, the present invention is not limited to this.

In another embodiment of the present invention, in the case of a polymer organic layer formed of a polymer organic material, the HTL 522 may be formed using poly-(2,4)-ethylene-dihydroxy thiophene (PEDOT) or polyaniline (PANI) in the direction of the first electrode 51, based on the organic light emitting layer 523. In this case, the HTL 522 is formed on the first electrode 51 by using inkjet printing or spin coating. PPV, soluble PPV's, Cyano-PPV, or polyfluorene may be used in forming the polymer organic light emitting layer 523. Color patterns may be formed using general methods, such as inkjet printing, spin coating, or thermal transfer using laser.

As described above, the organic light emitting display apparatus having a top gate structure shown in FIG. 2 has been described. However, as described above, the present invention is not limited to this and may be applied to various suitable types of organic light emitting display apparatuses.

Referring to FIG. 4, a sealing member 20 is prepared to face one side of the substrate 10. A bonding material 21 corresponds to the outer sidewall of the display portion 11 so as to join the substrate 10 and the sealing member 20 together.

The sealing member 20 is formed to passivate the organic light emitting device 50 from external moisture or oxygen. In the case of a front emission structure, the sealing member 20 is formed of a transparent material. To this end, the sealing member 20 may be formed of glass, plastic, or an overlapped structure of a plurality of organic materials and inorganic materials.

The bonding material 21 is formed on the sealing member 20 or the substrate 10, and the substrate 10 and the sealing member 20 are joined to each other, as illustrated in FIG. 4.

The bonding material 21 may be formed using various materials, such as glass frit or UV curing sealant. The bonding material 21 is formed to a sufficient thickness to secure the thickness of the display portion 11 formed on the substrate 10. If the thickness of the bonding material 21 is too large, light is scattered, and image quality is degraded. Therefore, the bonding material 21 is formed to a proper thickness in consideration of process conditions.

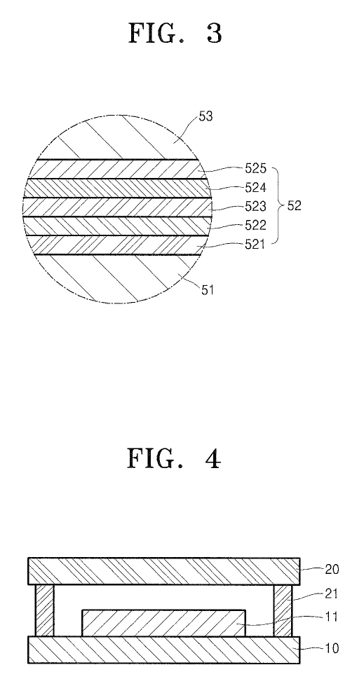

FIG. 5 is a graph showing a variation in brightness when the organic light emitting display apparatus of FIG. 4 is kept at a high temperature immediately before an aging operation. Specifically, FIG. 5 illustrates the case where the organic light emitting display apparatus of FIG. 4 is kept at 80 degrees Celsius (C), and its brightness is measured according to time. In other words, after a plurality of organic light emitting display apparatuses, as illustrated in FIG. 4, are manufactured, a high temperature reliability test is conducted on an organic light emitting display apparatus that is selected by sampling the plurality of organic light emitting display apparatuses. Referring to FIG. 5, the x-axis represents time and the y-axis represents brightness. In this case, brightness is not actually-measured brightness. Initial brightness, i.e., brightness immediately before the organic light emitting display apparatus of FIG. 4 is kept at a temperature of 80 degrees C., is defined as 1. For example, 0.8 of brightness means that brightness of the organic light emitting display apparatus of FIG. 4 is reduced by 80% compared to initial brightness. In each character illustrated in FIG. 5, W represents white brightness, R represents red brightness, G represents green brightness and B represents blue brightness. As can be understood from FIG. 5, the amount of reduction in green brightness is large. In particular, the amount of reduction in brightness is large within 25 hours, which is an initial stage of a test, and after 25 hours, a variation in the amount is not large. Due to the reduction in green brightness, the amount of reduction in white brightness increases. Such initial brightness variation causes a problem in the stable operation of the organic light emitting display device.

As can be understood from the above, in order to reduce or prevent the brightness reduction effect of the organic light emitting display apparatus at a high temperature of 80 degrees C. or more, in the method of manufacturing the organic light emitting display apparatus according to an embodiment of the present invention, an aging operation including thermal treatment is performed after the organic light emitting device 50 is sealed. In other words, the method of manufacturing the organic light emitting display apparatus according to an embodiment of the present invention includes a thermal aging operation at a high temperature. The temperature during the thermal aging operation may be in a range from about 80 to about 150 degrees C. (or from 80 to 150 degrees C.). As can be understood from the above, a problem in terms of the reliability of the organic light emitting display apparatus at a high temperature generally occurs at 80 degrees C. or more. Thus, the thermal aging operation is performed at 80 degrees C or more. However, when the thermal aging operation is performed at too high a temperature, a problem may occur in the organic light emitting device 50 that is vulnerable to heat. In general, since the transition temperature of organic materials included in the intermediate layer 52 of the organic light emitting device 50 is approximately 150 degrees C., the thermal aging operation is performed at about 150 degrees C. or less.

In the method of manufacturing the organic light emitting display apparatus according to an embodiment of the present invention, time required for the thermal aging operation is in a range of about 10 minutes to about 5 hours (or from 10 minutes to 5 hours). When the time period of the thermal aging operation is too short, an aging effect may not be enough, so the thermal aging operation is performed for about 10 minutes or more. When the time period of the thermal aging operation is too long, the aging effect is large, but productivity decreases. Thus, in view of process efficiency, the thermal aging operation may be performed for about 5 hours or less.

When the aging operation, including thermal treatment according to an embodiment of the present invention, is performed, brightness is reduced. Table 1 shows measurement results of luminous efficiency before and after the thermal aging operation is performed and data comparing the measurement results.

TABLE 1

| | | | Luminous efficiency |
|---|---|---|---|
| | Luminous | | after |
| | efficiency | Luminous | aging/luminous |
| | before aging | efficiency | efficiency before |
| Aging conditions | (cd/A) | after aging (cd/A) | aging (%) |
| E | 52.6 | 45.6 | 87% |
| F | 53.6 | 42.9 | 80% |
| G | 50.9 | 37.5 | 74% |
| H | 51 | 35.7 | 70% |

Table 1 shows only cases under four conditions. This shows that, in order to simplify experiments, four conditions are selected and experiments are performed within the range of temperature and time appropriate for the thermal aging operation according to an embodiment of the present invention. In addition, only a variation in green brightness, which had a relatively large variation rate, was measured.

Under the condition E, after the thermal aging operation was performed at 90 degrees C. for 2 hours, a green luminous effect was measured. Luminous efficiency before the thermal aging operation was 52.6 cd/A, and luminous efficiency after the thermal aging operation was 45.6 cd/A. It can be understood that luminous efficiency is reduced to 87%.

Under the condition F, after the thermal aging operation was performed at 90 degrees C. for 4 hours, a green luminous effect was measured. Luminous efficiency before the thermal aging operation was 53.6 cd/A, and luminous efficiency after the thermal aging operation was 42.9 cd/A. It can be understood that luminous efficiency is reduced to 80%.

Under the condition G, after the thermal aging operation was performed at 110 degrees C. for 2 hours, a green luminous effect was measured. Luminous efficiency before the thermal aging operation was 50.9 cd/A, and luminous efficiency after the thermal aging operation was 37.5 cd/A. It can be understood that luminous efficiency is reduced to 74%.

Under the condition H, after the thermal aging operation was performed at 110 degrees C. for 4 hours, a green luminous effect was measured. Luminous efficiency before the thermal aging operation was 51 cd/A, and luminous efficiency after the thermal aging operation was 35.7 cd/A. It can be understood that luminous efficiency is reduced to 70%.

As can be understood from Table 1, as temperature for the thermal aging operation increases and time required for the same is increased, the amount of reduction in luminous efficiency is increased. As the amount of luminous efficiency is increased when the organic light emitting display apparatus is kept at a high temperature, the amount of variation in brightness is small and the reliability of the organic light emitting display apparatus is improved when it is used at a high temperature.

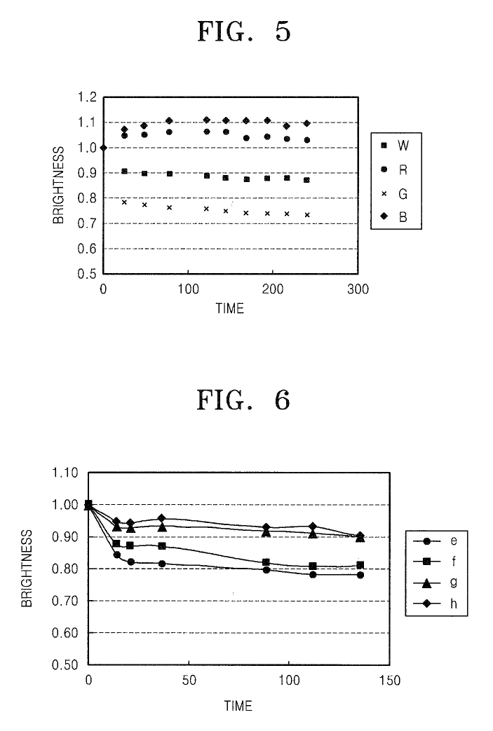

FIG. 6 is a graph showing a variation in brightness when the organic light emitting display apparatus of FIG. 4 is kept at a high temperature immediately after an aging operation. Specifically, FIG. 6 illustrates the brightness of the organic light emitting display apparatus of FIG. 4, which is kept at 80 degrees C. and measured according to time. Referring to FIG. 6, the x-axis represents time and the y-axis represents brightness. In this case, brightness is not actually measured brightness. Initial brightness, i.e., brightness immediately before the organic light emitting display apparatus of FIG. 4 is kept at a temperature of 80 degrees C., is defined as 1. For example, 0.8 of brightness means that brightness of the organic light emitting display apparatus of FIG. 4 is reduced by 80% compared to initial brightness. In order to simplify experiments, only a variation in green brightness, which has a relatively large variation rate, was measured.

Conditions E, F, G and H of FIG. 6 are the same as those of Table. 1. In other words, under the condition E, after the thermal aging operation was performed at 90 degrees C. for 2 hours and the organic light emitting display apparatus of FIG. 4 was kept at 80 degrees C., a variation in brightness according to time was measured; under the condition F, after the thermal aging operation was performed at 90 degrees C. for 4 hours and the organic light emitting display apparatus of FIG. 4 was kept at 80 degrees C, a variation in brightness according to time was measured; under the condition G, after the thermal aging operation was performed at 110 degrees C. for 2 hours and the organic light emitting display apparatus of FIG. 4 was kept at 80 degrees C., a variation in brightness according to time was measured; and under the condition H, after the thermal aging operation was performed at 110 degrees C. for 4 hours and the organic light emitting display apparatus of FIG. 4 was kept at 80 degrees C., a variation in brightness according to time was measured.

As can be understood from FIG. 6, as a result of performing the thermal aging operation according to an embodiment of the present invention, even when the organic light emitting display apparatus of FIG. 4 was kept at 80 degrees C., a reduction in brightness according to time is not large and the stability of the image quality is improved or secured. This can be better understood by comparison with FIG. 5. In other words, in FIG. 5, when approximately 10 hours have elapsed, green brightness is reduced to 80% or less and after 100 hours, green brightness is reduced to nearly 70%. However, it can be understood from FIG. 6 that, even in the case of the condition E, after 150 hours, green brightness is reduced to nearly 80%.

A method of manufacturing the organic light emitting display apparatus according to an embodiment of the present invention includes the thermal aging operation. In this case, the thermal aging operation includes thermal treatment in a range from about 80 to about 150 degrees C. Thus, even when the organic light emitting display apparatus is utilized at a high temperature, brightness is less likely to be (or prevented from being) rapidly reduced, and the stability of image quality can be improved.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A method of manufacturing an organic light emitting display apparatus, the method comprising:
forming an organic light emitting device comprising a first electrode, a second electrode, and an intermediate layer between the first electrode and the second electrode, on a substrate, the intermediate layer comprising an organic light emitting layer and an electron transport layer (ETL) containing an alkali metallic compound on the organic light emitting layer;
sealing the organic light emitting device; and
aging the organic light emitting device, wherein the aging comprises thermal treatment at a temperature from about 80 to about 150 degrees C.

2. The method of claim 1, wherein the alkali metallic compound comprises one material selected from the group consisting of LiQ, NaQ, LiF, and combinations thereof.

3. The method of claim 1, wherein the thermal treatment is performed for time period from about 10 minutes to about 5 hours.

4. The method of claim 1, wherein the alkali metallic compound in the ETL comprises a ½ molar fraction.

5. The method of claim 1, wherein from about 30 to about 70 wt % of the alkali metallic compound is contained in the ETL.

6. The method of claim 1, further comprising forming an electron injection layer (EIL) between the ETL and the second electrode.

7. An organic light emitting display apparatus comprising:
a substrate;
an organic light emitting device comprising a first electrode on the substrate, a second electrode on the first electrode, and an intermediate layer between the first electrode and the second electrode, the intermediate layer comprising an organic light emitting layer and an electron transport layer (ETL) containing an alkali metallic compound on the organic light emitting layer; and
a sealing member sealing the organic light emitting device, wherein the organic light emitting device is aged at a temperature from about 80 to about 150 degrees C.

8. The apparatus of claim 7, wherein the alkali metallic compound comprises one material selected from the group consisting of LiQ, NaQ, LiF, and combinations thereof.

9. The apparatus of claim 7, wherein the alkali metallic compound is contained in the ETL at ½ molar fraction.

10. The apparatus of claim 7, wherein from about 30 to about 70 wt % of the alkali metallic compound is contained in the ETL.

11. A system of manufacturing an organic light emitting display apparatus, the system comprising:
means for forming an organic light emitting device comprising a first electrode, a second electrode, and an intermediate layer between the first electrode and the second electrode, on a substrate, wherein the intermediate layer comprises an organic light emitting layer and an electron transport layer (ETL) containing an alkali metallic compound on the organic light emitting layer;
means for sealing the organic light emitting device; and
means for aging the organic light emitting device with a thermal treatment at a temperature ranging from about 80 to about 150 degrees C.

12. The system of claim 11, wherein the alkali metallic compound comprises one material selected from the group consisting of LiQ, NaQ, LiF, and combinations thereof.

13. The system of claim 11, wherein the thermal treatment is performed for time period from about 10 minutes to about 5 hours.

14. The system of claim 11, wherein the alkali metallic compound in the ETL comprises a ½ molar fraction.

15. The system of claim 11, wherein from about 30 to about 70 wt % of the alkali metallic compound is contained in the ETL.

16. The system of claim 11, further comprising forming an electron injection layer (EIL) between the ETL and the second electrode.
